(19) United States
(12) Patent Application Publication
(10) Pub. No.: US 2016/0217903 A1
(43) Pub. Date: Jul. 28, 2016

(54) ELECTRONIC COMPONENT

(71) Applicant: SAMSUNG ELECTRO-MECHANICS CO., LTD., Suwon-si (KR)

(72) Inventor: Dong Jin JEONG, Suwon-si (KR)

(21) Appl. No.: 14/934,986

(22) Filed: Nov. 6, 2015

(30) Foreign Application Priority Data
Jan. 28, 2015 (KR) 10-2015-0013430

(51) Int. Cl. H01F 27/26; H01F 27/29

(52) U.S. Cl. CPC H01F 27/263; H01F 27/29

(57) ABSTRACT

An electronic component includes a first magnetic body in which a first internal coil part is embedded; a second magnetic body in which a second internal coil part is embedded; and a spacer part disposed between the first and second magnetic bodies and connecting the first and second magnetic bodies to each other.

### CROSS-REFERENCE TO RELATED APPLICATION

This application claims the benefit of priority to Korean Patent Application No. 10-2015-0013430, filed on Jan. 28, 2015 with the Korean Intellectual Property Office, the entirety of which is incorporated herein by reference.

### TECHNICAL FIELD

The present disclosure relates to an electronic component and a board having the same.

### BACKGROUND

An inductor, an electronic component, is a representative passive element configuring an electronic circuit, together with a resistor and a capacitor, to remove noise therefrom.

In order to decrease an area required for the mounting of passive elements on a printed circuit board, an array-type inductor in which a plurality of internal coil parts are disposed may be used.

### SUMMARY

An aspect of the present disclosure provides an electronic component capable of suppressing harmful mutual interference of magnetic fields generated by a plurality of internal coil parts, and a board having the same.

According to an aspect of the present disclosure, an electronic component includes a first magnetic body in which a first internal coil part is embedded, and a second magnetic body in which a second internal coil part is embedded. A spacer part disposed between the first and second magnetic bodies connects the first and second magnetic bodies to each other.

The spacer part may contain at least one selected from the group consisting of a thermosetting resin, a magnetic metal powder, ferrite, and a dielectric material.

The spacer part may be made of a material different from a material of the magnetic body.

The bonding strength between the first and second magnetic bodies may be 4.9 N or more.

The width of the spacer part may satisfy 3 μm<a<30 μm, where “a” is a width of the spacer part.

The thickness of the spacer part may be 30% to 100% of a thickness of the first and second magnetic bodies.

The length of the spacer part may be 30% to 100% of a length of the first and second magnetic bodies.

The magnetic bodies may contain magnetic metal powder and a thermosetting resin.

The first and second internal coil parts may be electroplated materials.

The first and second internal coil parts may include first and second lead portions exposed to first and second end surfaces of the first and second magnetic bodies in a length direction, respectively. The first lead portions are connected to first and third external electrodes disposed on the first end surfaces of the first and second magnetic bodies, and the second lead portions are connected to second and fourth external electrodes disposed on the second end surfaces of the first and second magnetic bodies.

According to another aspect of the present disclosure, an electronic component includes a first magnetic body in which a first internal coil part is embedded. The first internal coil part includes coil conductors disposed on first and second surfaces of a first support member. The electronic component further includes a second magnetic body in which a second internal coil part is embedded. The second internal coil part includes coil conductors disposed on first and second surfaces of a second support member. A spacer part is disposed between the first and second magnetic bodies, suppressing mutual interference of magnetic fields generated by the first and second internal coil parts, and connecting the first and second magnetic bodies to each other.

The spacer part may have a magnetic permeability lower than that of the first and second magnetic bodies.

### BRIEF DESCRIPTION OF DRAWINGS

The above and other aspects, features and advantages of the present disclosure will be more clearly understood from the following detailed description taken in conjunction with the accompanying drawings, in which:

FIG. 1 is a perspective view of an electronic component according to an exemplary embodiment in the present disclosure;

FIG. 2 is a perspective view of internal coil parts in the electronic component according to the exemplary embodiment in the present disclosure;

FIGS. 3A and 3B are plan views of an internal portion of the electronic component projected in directions A and B of FIG. 2;

FIG. 4 is a cross-sectional view taken along line I-I′ of FIG. 1; and

FIG. 5 is a perspective view of a board in which the electronic component of FIG. 1 is mounted on a printed circuit board (PCB).

### DETAILED DESCRIPTION

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

### Electronic Component

Hereinafter, an electronic component, particularly, a thin film-type inductor, according to exemplary embodiments, will be described. However, the electronic component according to exemplary embodiments is not limited thereto.

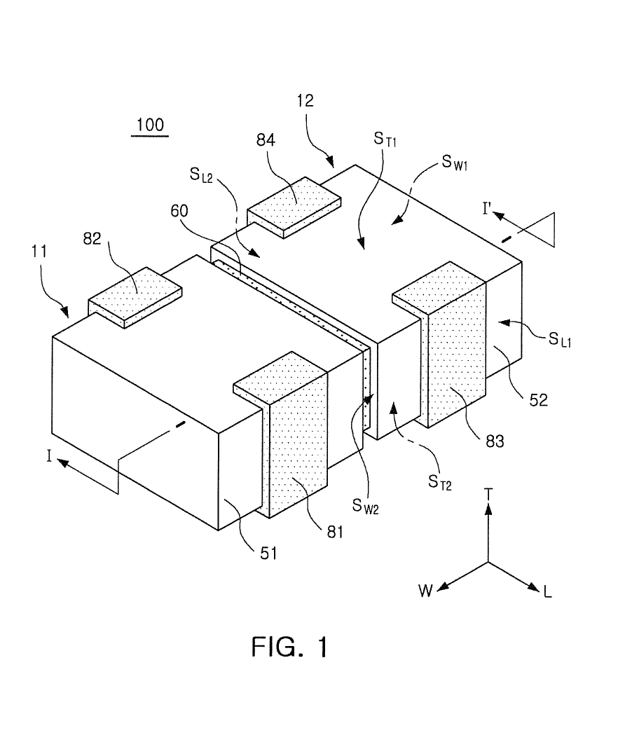

FIG. 1 is a perspective view of an electronic component according to an exemplary embodiment.

Referring to FIG. 1, an electronic component 100 according to the exemplary embodiment may include a first magnetic body 51, a second magnetic body 52, first to fourth external electrodes 81, 82, 83, 84 disposed on external surfaces of the first and second magnetic bodies 51 and 52, and a spacer part 60 disposed between the first and second magnetic bodies 51 and 52.

In the exemplary embodiment, ordinal numbers such as “first and second”, “first to fourth”, and the like, are used in order to distinguish objects, and are not limited to the order thereof.

In the electronic component 100 according to an exemplary embodiment, a ‘length’ direction of the magnetic body refers to an ‘L’ direction of FIG. 1, a ‘width’ direction of the magnetic body refers to a ‘W’ direction of FIG. 1, and a ‘thickness’ direction of the magnetic body refers to a ‘T’ direction of FIG. 1.

The first and second magnetic bodies 51 and 52 may have first and second end surfaces S_{L1} and S_{L2} opposing each other in the length (L) direction thereof, first and second side surfaces S_{W1} and S_{W2} connecting the first and second end surfaces S_{L1} and S_{L2} to each other and opposing each other in the width (W) direction thereof, and first and second main surfaces S_{T1} and S_{T2} opposing each other in the thickness (T) direction thereof, respectively.

The first and second magnetic bodies 51 and 52 may contain any material as long as the material exhibits magnetic properties. For example, the first and second magnetic bodies 51 and 52 may contain ferrite or magnetic metal powder.

The ferrite may be, for example, an Mn—Zn based ferrite, an Ni—Zn based ferrite, an Ni—Zn—Cu based ferrite, an Mn—Mg based ferrite, a Ba based ferrite, or an Li based ferrite.

The magnetic metal powder may be crystalline or amorphous metal powder containing one or more selected from the group consisting of iron (Fe), silicon (Si), boron (B), chromium (Cr), aluminum (Al), copper (Cu), niobium (Nb), and nickel (Ni).

For example, the magnetic metal powder may be Fe—Si—B—Cr based amorphous metal powder.

The magnetic metal powder may be dispersed in a thermosetting resin such as an epoxy resin or polyimide, to thereby be contained in the first and second magnetic bodies 51 and 52.

The electronic component 100 according to the exemplary embodiment may include a first electronic component 11 including the first magnetic body 51 and a second electronic component 12 including the second magnetic body 52, and the spacer part 60 may be disposed between the first and second electronic components 11 and 12, thereby connecting the first and second electronic components 11 and 12 to each other.

The first electronic component 11 may include the first magnetic body 51 and the first and second external electrodes 81 and 82 formed on the first and second end surfaces S_{L1} and S_{L2} of the first magnetic body 51. The second electronic component 12 may include the second magnetic body 52 and the third and fourth external electrodes 83 and 84 formed on the first and second end surfaces S_{L1} and S_{L2} of the second magnetic body 52.

The first and second external electrodes 81 and 82 may be formed on the first and second end surfaces S_{L1} and S_{L2} of the first magnetic body 51 and extended to the first and second main surfaces S_{T1} and S_{T2} of the first magnetic body 51 in the thickness (T) direction. The third and fourth external electrodes 83 and 84 may be formed on the first and second end surfaces S_{L1} and S_{L2} of the second magnetic body 52 and extended to the first and second main surfaces S_{T1} and S_{T2} of the second magnetic body in the thickness (T) direction.

The first to fourth external electrodes 81 to 84 may be disposed to be spaced apart from each other to thereby be electrically separated from each other.

The first to fourth external electrodes 81 to 84 may be formed of a metal having excellent electrical conductivity, for example, silver (Ag), palladium (Pd), aluminum (Al), nickel (Ni), titanium (Ti), gold (Au), copper (Cu) , platinum (Pt), or alloys thereof.

The spacer part 60 may be formed to contact the first side surface S_{W1} of the first magnetic body 51 and the second side surface S_{W2} of the second magnetic body 52 to thereby serve to bond the first and second electronic components 11 and 12, which are individual electronic components, to each other.

A specific feature of the spacer part 60 will be described below.

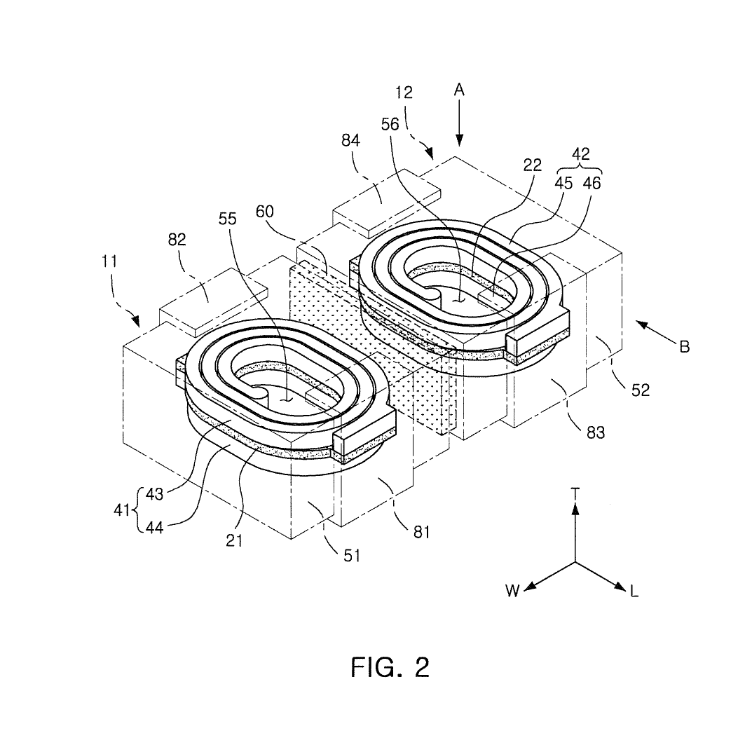

FIG. 2 is a perspective view of internal coil parts in the electronic component according to the exemplary embodiment.

Referring to FIG. 2, as an example of the electronic component, a thin film-type inductor used for a power line of a power supply circuit is disclosed.

The electronic component 100 according to the exemplary embodiment may include the first electronic component 11 including the first magnetic body 51 in which a first internal coil part 41 is embedded and the second electronic component 12 including the second magnetic body 52 in which a second internal coil part 42 is embedded.

The first and second magnetic bodies 51 and 52, in which the first and second internal coil parts 41 and 42 are embedded, respectively, may be bonded to each other by the spacer part 60, thereby forming a single electronic component 100.

That is, the electronic component 100 according to the exemplary embodiment maybe an array-type inductor having a basic structure in which two or more internal coil parts are disposed.

The first and second internal coil parts 41 and 42 may be formed by connecting first coil conductors 43 and 45 formed on first surfaces of first and second support members 21 and 22 disposed in the first and second magnetic bodies 51 and 52 to second coil conductors 44 and 46 formed on second surfaces of the first and second support members 21 and 22 opposing the first surfaces thereof, respectively.

The first and second coil conductors 43 to 46 may have the form of planar coils formed on the same planes of the first and second support members 21 and 22, respectively.

The first and second coil conductors 43 to 46 may be formed in a spiral shape. The first and second coil conductors 43 and 44 formed on the first and second surfaces of the first support member 21 may be electrically connected to each other by a via (not illustrated) penetrating through the first support member 21. The first and second coil conductors 45 and 46 formed on the first and second surfaces of the second support member 22 may be electrically connected to each other by a via (not illustrated) penetrating through the second support member 22.

The first and second coil conductors 43 to 46 may be formed by performing electroplating on the support members 21 and 22, but a method of forming the first and second coil conductors 43 to 46 is not limited thereto.

The first and second coil conductors 43 to 46 and the vias maybe formed of a metal having excellent electric conductivity, for example, silver (Ag), palladium (Pd), aluminum (Al), nickel (Ni), titanium (Ti), gold (Au), copper (Cu), platinum (Pt), or alloys thereof.

The first and second coil conductors 43 to 46 maybe coated with an insulation film (not illustrated) to thereby not directly contact the magnetic material forming the first and second magnetic bodies 51 and 52.

The first and second support members 21 and 22 may be, for example, a polypropylene glycol (PPG) substrate, a ferrite substrate, or a metal-based soft magnetic substrate.

The first and second support members 21 and 22 may have through holes formed in central portions thereof to penetrate through the central portions thereof, wherein the through holes are filled with a magnetic material, thereby forming first and second core parts 55 and 56. That is, the first and second core parts 55 and 56 may be formed inwardly of the first and second internal coil parts 41 and 42, respectively.

As the first and second core parts 55 and 56 made of the magnetic material are formed inwardly of the first and second internal coil parts 41 and 42, inductance L may be improved.

The first and second internal coil parts 41 and 42 may be disposed in the first and second magnetic bodies 51 and 52, respectively, and the spacer part 60 may be disposed between the first and second magnetic bodies 51 and 52 to bond the first and second magnetic bodies 51 and 52 to each other.

According to the exemplary embodiment, the spacer part 60 maybe disposed between the first and second internal coil parts 41 and 42, such that harmful mutual interference of the magnetic fields generated by the plurality of internal coil parts may be suppressed.

That is, the spacer part 60 may be disposed between the first and second magnetic bodies 51 and 52 to serve to suppress harmful mutual interference of the magnetic fields generated by the first and second internal coil parts 41 and 42 while connecting the first and second magnetic bodies 51 and 52 to each other.

In a case of an array-type electronic component in which a plurality of internal coil parts are disposed, a product may malfunction and efficiency may be deteriorated due to harmful interference between the internal coil parts.

Furthermore, as electronic components have been miniaturized, intervals between a plurality of internal coil parts in an array-type electronic component have been decreased, such that it maybe difficult to suppress harmful interference between the internal coil parts by only adjusting shapes of the internal coil parts and position relationships therebetween.

In an array-type electronic component in which the plurality of internal coil parts are embedded, it may also be difficult to completely insulate a leakage current.

Therefore, according to the exemplary embodiment, there is provided an array-type electronic component having improved insulation properties with respect to the leakage current. The array-type electronic component also effectively suppresses harmful mutual interference of the magnetic fields generated by the plurality of internal coil parts by having a structure including the first electronic component 11 including the first magnetic body 51 in which the first internal coil part 41 is embedded and the second electronic component 12 including the second magnetic body 51 in which the second internal coil part 42 is embedded, and forming the spacer part 60 connecting the first and second electronic components 11 and 12 to each other between the first and second magnetic bodies 51 and 52.

The spacer part 60 may be formed of any material as long as the material may bond the first and second magnetic bodies 51 and 52 to each other and may suppress harmful mutual interference of the magnetic fields generated by the first and second internal coil parts 41 and 42, and may be formed of a material different from that of the first and second magnetic bodies 51 and 52.

The material different from that of the first and second magnetic bodies 51 and 52 may also include a material in which the same raw material is contained but a composition thereof, or the like, is different.

For example, the spacer part 60 may contain one or more selected from the group consisting of a thermosetting resin, magnetic metal powder, ferrite, and a dielectric material.

Meanwhile, according to the exemplary embodiment, a coupling value may be controlled by changing the material of the spacer part 60 to adjust mutual interference between the first and second internal coil parts 41 and 42.

The spacer part 60 may have magnetic permeability lower than that of the first and second magnetic bodies 51 and 52. Therefore, the spacer part 60 may suppress harmful mutual interference of the magnetic fields generated by the first and second internal coil parts 41 and 42.

Bonding strength between the first and second magnetic bodies 51 and 52 bonded to each other by the spacer part 60 may be 4.9 N or more.

In a case in which bonding strength between the first and second magnetic bodies 51 and 52 is less than 4.9 N, at the time of mounting the electronic component on a printed circuit board, the first and second magnetic bodies 51 and 52 may be separated from each other, and the electronic component 100 may be broken.

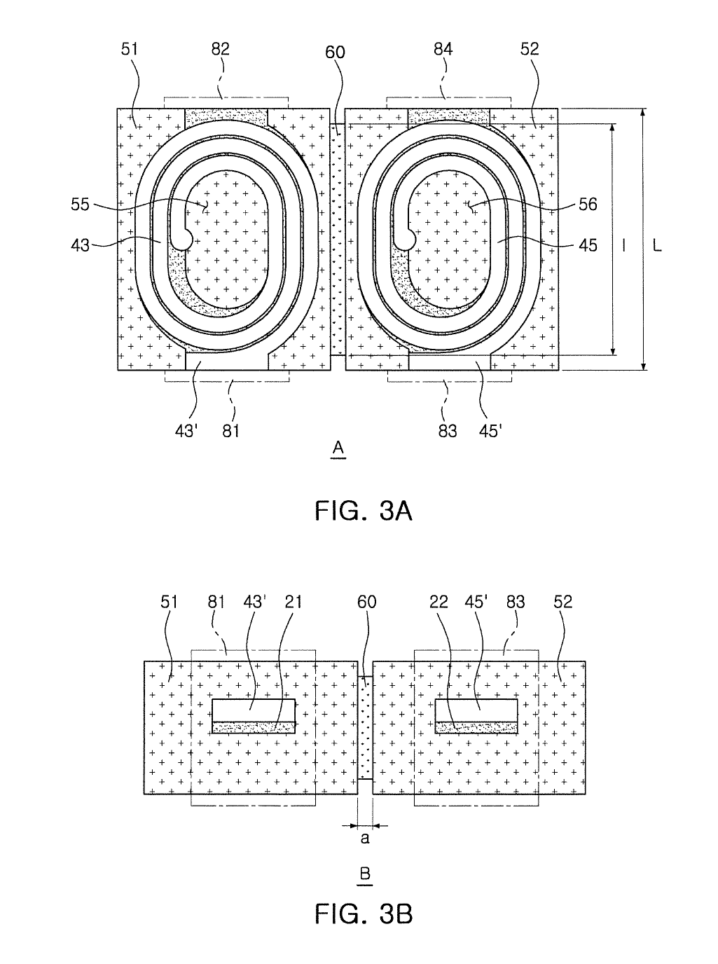

FIG. 3A is a plan view of an internal portion of the electronic component projected in direction A of FIG. 2, and FIG. 3B is a plan view of the internal portion of the electronic component projected in direction B of FIG. 2.

Referring to FIG. 3A, the first and second internal coil parts 41 and 42 may include first lead portions 43′ and 45′ extended from end portions of the first coil conductors 43 and 45 and exposed to the first end surfaces S_{L1} of the first and second magnetic bodies 51 and 52 and second lead portions (not illustrated) extended from end portions of the second coil conductors 44 and 46 and exposed to the second end surfaces S_{L2} of the first and second magnetic bodies 51 and 52, respectively.

The first lead portions 43′ and 45′ may be connected to the first and third external electrodes 81 and 83 disposed on the first end surfaces S_{L1} of the first and second magnetic bodies 51 and 52 and second lead portions (not illustrated) may be connected to the second and fourth external electrodes 82 and 84 disposed on the second end surfaces S_{L2} of the first and second magnetic bodies 51 and 52.

The first and third external electrodes 81 and 83 may be input terminals, and the second and fourth external electrodes 82 and 84 may be output terminals, but the first to fourth external electrodes 81 to 84 are not limited thereto.

For example, a current input to the first external electrode 81, the input terminal, may sequentially pass through the first coil conductor 43 of the first internal coil part 41, the via, and the second coil conductor 44 of the first internal coil part 41 to thereby flow to the second external electrode 82, the output terminal.

Similarly, a current input to the third external electrode 83, the input terminal, may sequentially pass through the first coil conductor 45 of the second internal coil part 42, the via, and the second coil conductor 46 of the second internal coil part 42 to thereby flow to the fourth external electrode 84, the output terminal.

However, the first to fourth external electrodes 81 to 84 are not limited thereto, but the first and fourth external electrodes 81 and 84 may be input terminals, and the second and third external electrodes 82 and 83 may be output terminals.

A length l of the spacer part 60 according to the exemplary embodiment may be 30% to 100% of a length L of the first and second magnetic bodies 51 and 52.

When the length l of the spacer part 60 is less than 30% of the length L of the first and second magnetic bodies 51 and 52, an effect of suppressing harmful mutual interference of the magnetic fields may be decreased, and bonding strength may be decreased, such that when the electronic component is mounted on a printed circuit board, the first and second magnetic bodies 51 and 52 may be separated from each other. When the length l of the spacer part 60 is greater than 100% of the length L of the first and second magnetic bodies 51 and 52, the effect of suppressing harmful mutual interference of the magnetic fields may not be significantly increased, but the spacer part 60 may unnecessarily occupy an area of the printed circuit board at the time of mounting the electronic component thereon.

Meanwhile, according to the exemplary embodiment, the coupling value may be controlled by changing the length l of the spacer part 60 to adjust mutual interference between the first and second internal coil parts 41 and 42.

Referring to FIG. 3B, a width a of the spacer part 60 may satisfy 3 μm<a<30 μm.

When the width a of the spacer part 60 is less than 3 μm, bonding strength may be decreased, and malfunctioning of a product may occur and efficiency may be deteriorated due to harmful mutual interference of the magnetic fields generated by the first and second internal coil parts 41 and 42. When the width a of the spacer part 70 is greater than 30 μm, the effect of suppressing harmful mutual interference of the magnetic fields may not be significantly increased, but it may be difficult to miniaturize the electronic component.

According to the exemplary embodiment, the coupling value may be controlled by changing the width a of the spacer part 60 to adjust mutual interference between the first and second internal coil parts 41 and 42.

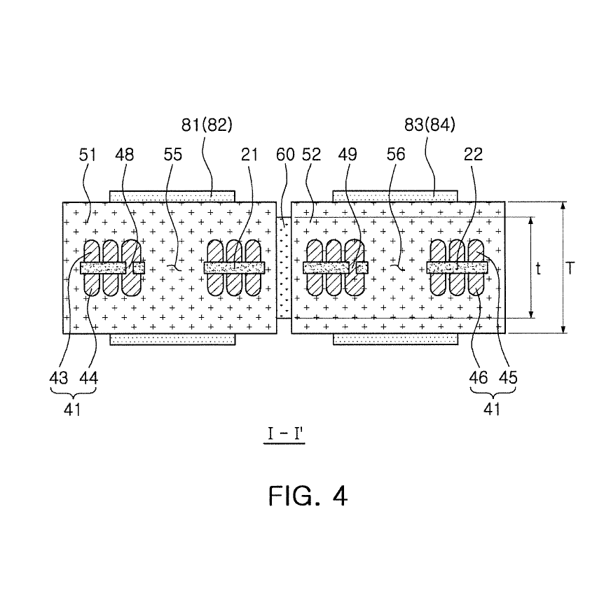

FIG. 4 is a cross-sectional view taken along line I-I′ of FIG. 1.

Referring to FIG. 4, the first coil conductors 43 and 45 disposed on first surfaces of the first and second support members 21 and 22 and the second coil conductors 44 and 46 disposed on second surfaces of the first and second support members 21 and 22 may be connected to each other by vias 48 and 49 penetrating through the first and second support members 21 and 22.

A thickness t of the spacer part 60 according to the exemplary embodiment in the present disclosure maybe 30% to 100% of a thickness T of the first and second magnetic bodies 51 and 52.

When the thickness t of the spacer part 60 is less than 30% of the thickness T of the first and second magnetic bodies 51 and 52, the effect of suppressing harmful mutual interference of the magnetic fields maybe decreased, and bonding strength may be decreased, such that when the electronic component is mounted on a printed circuit board, the first and second magnetic bodies 51 and 52 may be separated from each other. When the thickness t of the spacer part 60 is greater than 100% of the thickness T of the first and second magnetic bodies 51 and 52, the effect of suppressing harmful mutual interference of the magnetic fields may not be significantly increased, but the spacer part 60 may occupy an area of the printed circuit board at the time of mounting the electronic component thereon.

Meanwhile, according to the exemplary embodiment, the coupling value may be controlled by changing the thickness t of the spacer part 60 to adjust mutual interference between the first and second internal coil parts 41 and 42.

### Board Having Electronic Component

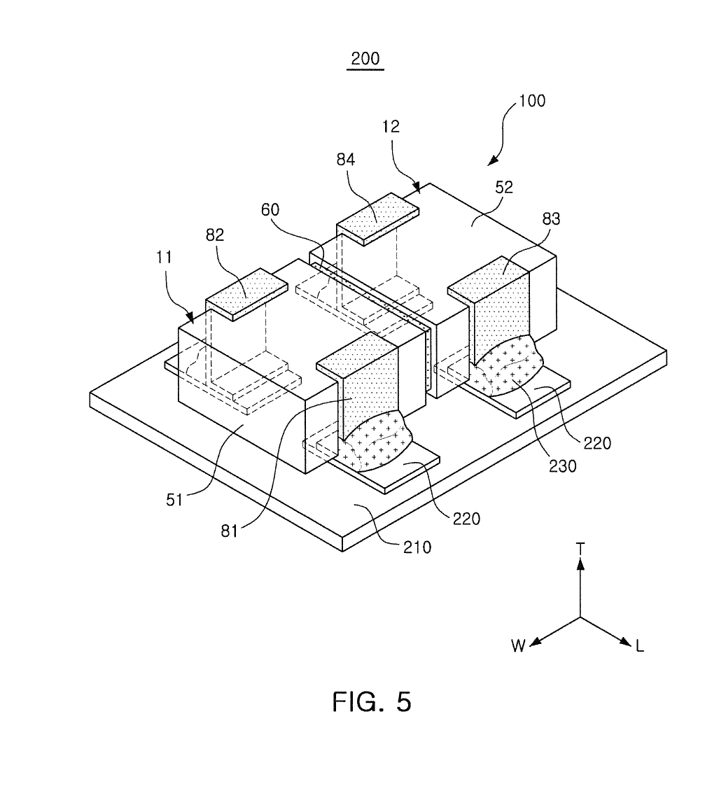

FIG. 5 is a perspective view of a board in which the electronic component of FIG. 1 is mounted on a printed circuit board (PCB).

Referring to FIG. 5, a board 200 having an electronic component 100 according to the present exemplary embodiment may include a printed circuit board 210 on which the electronic component 100 is mounted and a plurality of electrode pads 220 formed on the printed circuit board 210 to be spaced apart from each other.

The first to fourth external electrodes 81 to 84 disposed on the external surfaces of the electronic component 100 may be electrically connected to the printed circuit board 210 by solders 230 in a state in which the first to fourth external electrodes 81 to 84 are positioned to contact the electrode pads 220, respectively.

Except for the description above, descriptions of features overlapping those of the electronic component according to the previous exemplary embodiment will be omitted.

As set forth above, according to exemplary embodiments in the present disclosure, harmful mutual interference of the magnetic fields generated by the plurality of internal coil parts may be suppressed.

Further, the coupling values may be controlled by adjusting mutual interference between the plurality of internal coil parts.

While exemplary embodiments have been shown and described above, it will be apparent to those skilled in the art that modifications and variations could be made without departing from the scope of the present invention as defined by the appended claims.

What is claimed is:

1. An electronic component comprising:
a first magnetic body in which a first internal coil part is embedded;
a second magnetic body in which a second internal coil part is embedded; and
a spacer part disposed between the first and second magnetic bodies and connecting the first and second magnetic bodies to each other.

2. The electronic component of claim 1, wherein the spacer part contains at least one selected from the group consisting of a thermosetting resin, a magnetic metal powder, ferrite, and a dielectric material.

3. The electronic component of claim 1, wherein the spacer part is made of a material different from a material of the magnetic body.

4. The electronic component of claim 1, wherein a bonding strength between the first and second magnetic bodies is 4.9 N or more.

5. The electronic component of claim 1, wherein 3 μm<a<30 μm, where a is a width of the spacer part.

6. The electronic component of claim 1, wherein a thickness of the spacer part is 30% to 100% of a thickness of the first and second magnetic bodies.

7. The electronic component of claim 1, wherein a length of the spacer part is 30% to 100% of a length of the first and second magnetic bodies.

8. The electronic component of claim 1, wherein the magnetic bodies contain magnetic metal powder and a thermosetting resin.

9. The electronic component of claim 1, wherein the first and second internal coil parts are electroplated materials.

10. The electronic component of claim 1, wherein the first and second internal coil parts include first and second lead portions exposed to first and second end surfaces of the first and second magnetic bodies in a length direction, respectively,
the first lead portions are connected to first and third external electrodes disposed on the first end surfaces of the first and second magnetic bodies, and
the second lead portions are connected to second and fourth external electrodes disposed on the second end surfaces of the first and second magnetic bodies.

11. An electronic component comprising:
a first magnetic body in which a first internal coil part is embedded, the first internal coil part including coil conductors disposed on first and second surfaces of a first support member;
a second magnetic body in which a second internal coil part is embedded, the second internal coil part including coil conductors disposed on first and second surfaces of a second support member; and
a spacer part disposed between the first and second magnetic bodies, suppressing mutual interference of magnetic fields generated by the first and second internal coil parts, and connecting the first and second magnetic bodies to each other.

12. The electronic component of claim 11, wherein the spacer part has a magnetic permeability lower than that of the first and second magnetic bodies.

13. The electronic component of claim 11, wherein bonding strength between the first and second magnetic bodies is 4.9 N or more.
